(19) United States
(12) Patent Application Publication
(10) Pub. No.: US 2008/0087641 A1
(43) Pub. Date: Apr. 17, 2008

(54) Components for a plasma processing apparatus

(75) Inventors: Anthony De La Llera, Fremont, CA (US); Saurabh J. Ullal, South San Francisco, CA (US)

Correspondence Address: BUCHANAN, INGERSOLL & ROONEY PC, POST OFFICE BOX 1404, ALEXANDRIA, VA, 22313-1404, US

(73) Assignee: Lam Research Corporation, Fremont, CA (US)

(21) Appl. No.: 11/639,263

(22) Filed: Dec. 15, 2006

Related U.S. Application Data
(60) Provisional application No. 60/851,746, filed on Oct. 16, 2006.

(51) Int. Cl. H05H 1/24; C23F 1/00; H01L 21/306; H01L 21/302; C23C 16/00

(52) U.S. Cl. 216/67; 427/569; 438/689; 118/715; 156/345.24

(57) ABSTRACT

Components for a plasma processing apparatus are provided, including fastener members adapted to accommodate the stresses generated during thermal cycling. The fasteners include deflectable spacers to accommodate forces generated by the difference in thermal expansion while minimizing generation of additional particulate contamination.

### RELATED APPLICATIONS

This application claims priority under 35 U.S.C. 119 to U.S. Provisional Application No. 60/851,746 entitled COMPONENTS FOR A PLASMA PROCESSING APPARATUS and filed on Oct. 16, 2006, the entire content of which is hereby incorporated by reference.

### BACKGROUND

Plasma processing apparatuses are used to process substrates by techniques including etching, physical vapor deposition (PVD), chemical vapor deposition (CVD), ion implantation, and resist removal. One type of plasma processing apparatus used in plasma processing includes a reaction chamber containing upper and bottom electrodes. An electric field is established between the electrodes to excite a process gas into the plasma state to process substrates in the reaction chamber.

### SUMMARY

A component for a plasma processing apparatus is provided. The component includes a first member having a first coefficient of thermal expansion, a plurality of through apertures having a first portion and a second portion wider than the first portion. The second portion is partially defined by at least one load-bearing surface. The component includes a plurality of first fastener members having a second coefficient of thermal expansion, mounted in the apertures of the first member. The first fastener members include a load-bearing surface. At least one deflectable spacer is mounted between the load-bearing surface, defining the second portion of the aperture and the load-bearing surface of the first fastener member. A second fastener member engages with each first fastener member to secure the first member to the second member at a predetermined clamping force. The at least one deflectable spacer is adapted to accommodate forces generated during thermal cycling between room temperature and an elevated processing temperature.

In another embodiment, a component for a plasma processing apparatus is provided, including a first member having a first coefficient of thermal expansion. A second member includes a plurality of through apertures having a first portion and a second portion wider than the first portion. The second portion is partially defined by at least one load-bearing surface. A plurality of first fastener members having a second coefficient of thermal expansion is mounted in the apertures of the second member. The first fastener members include a load-bearing surface. At least one deflectable spacer is mounted between the load-bearing surface defining the second portion of the aperture and the load-bearing surface of the first fastener member. A second fastener member engages with each first fastener member to secure the first member to the second member at a predetermined clamping force, the at least one deflectable spacer adapted to accommodate forces generated during thermal cycling between room temperature and an elevated processing temperature.

In a preferred embodiment, the component is a showerhead electrode assembly in a plasma processing apparatus. The showerhead electrode assembly includes an aluminum thermal control plate including a plurality of through apertures having a first portion and a second portion wider than the first portion. The second portion is partially defined by at least one load-bearing surface. A plurality of stainless steel fastener members are mounted in the apertures of the thermal control plate, the first fastener members including a load-bearing surface. A plurality of deflectable spacers are mounted between the load-bearing surface of the second portion of the aperture and the load-bearing surface of the first fastener member. A second fastener member engages with each first fastener member to secure the thermal control plate to a backing member at a predetermined clamping force. The deflectable spacers are adapted to accommodate forces generated by the difference in thermal expansion between the thermal control plate and first fastener member during thermal cycling between room temperature and an elevated processing temperature. A silicon electrode can be attached to the backing plate.

A method of processing a semiconductor substrate in a plasma processing apparatus is provided. A substrate is placed on a substrate support in a reaction chamber of a plasma processing apparatus. A process gas is introduced into the reaction chamber with the showerhead electrode assembly. A plasma is generated from the process gas between the showerhead electrode assembly. The substrate is processed with the plasma.

### BRIEF DESCRIPTION OF THE FIGURES

FIG. 1 illustrates a portion of an embodiment of a showerhead electrode assembly and a substrate support for a plasma processing apparatus.

FIG. 2 illustrates a first fastener member and a second fastener member used to attach a thermal control plate to a backing member.

FIG. 3 illustrates a first fastener member and a second fastener member attaching a thermal control plate to a backing member at ambient temperature at a pre-determined clamping force.

FIG. 4 illustrates the configuration of FIG. 3 at an elevated processing temperature.

FIG. 5 illustrates a first fastener member and a second fastener member used to attach a thermal control plate to a backing member with a deflectable spacer member.

FIG. 6 illustrates an alternative fastening configuration, in which the first fastener member is inverted.

FIG. 7 illustrates a first fastener member and a second fastener member attaching a thermal control plate to a backing member at ambient temperature with a deflectable spacer member at a pre-determined clamping force.

FIG. 8 illustrates the configuration of FIG. 7 at an elevated processing temperature.

### DETAILED DESCRIPTION

Control of particulate contamination on the surfaces of semiconductor substrates, such as wafers, during the fabrication of integrated circuits is essential in achieving reliable devices and obtaining a high yield. Processing equipment, such as plasma processing apparatuses, can be a source of particulate contamination. For example, the presence of particles on the wafer surface can locally disrupt pattern transfer during photolithography and etching steps. As a result, these particles can introduce defects into critical features, including gate structures, intermetal dielectric layers or metallic interconnect lines, resulting in the malfunction or failure of the integrated circuit component.

Components of a plasma processing apparatus are provided that can reduce and preferentially minimize particulate contamination. The components include fastener members that can accommodate the stresses generated during thermal cycling of the plasma processing components, due to the differences in coefficient of thermal expansion of members of the component, with the minimal generation of additional particulate contamination. The fastener members can be used to fasten any members of various components, in which both members are heated and undergo thermal expansion during plasma processing. Methods of processing semiconductor substrates in plasma processing chambers containing one or more such components are also provided.

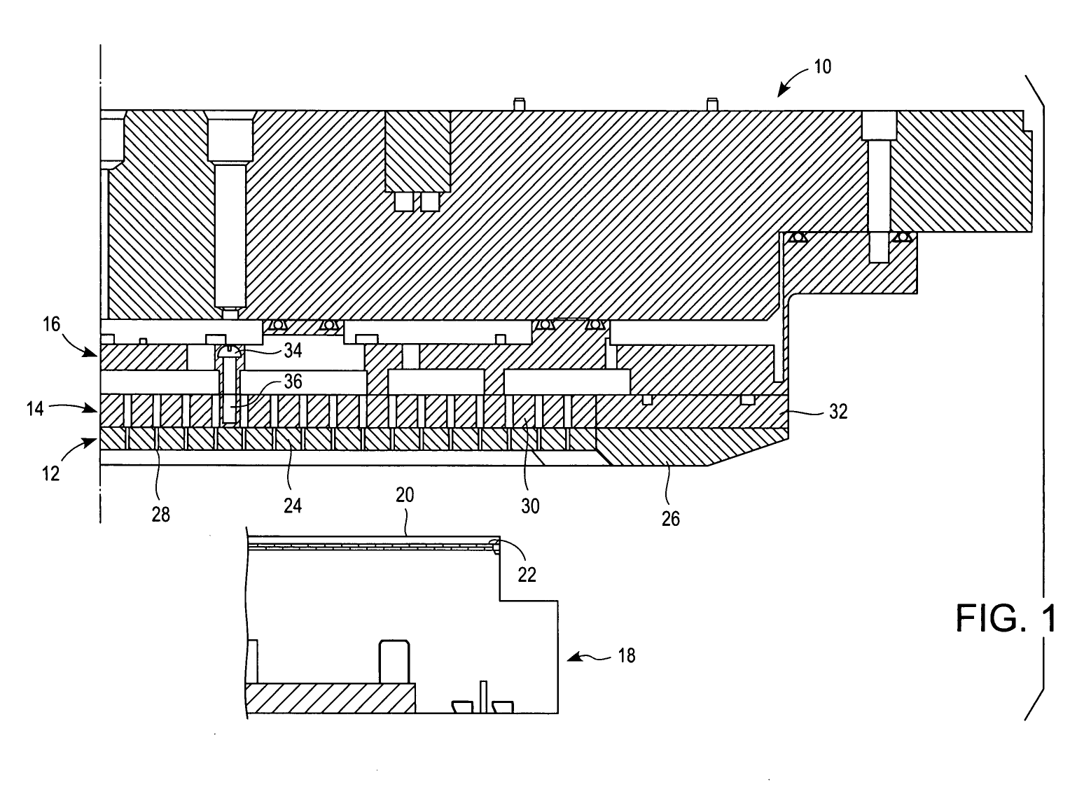

FIG. 1 illustrates an exemplary embodiment of a showerhead electrode assembly 10 for a plasma processing apparatus in which semiconductor substrates, e.g., silicon wafers, are processed. The showerhead electrode assembly is described, for example, in commonly-owned U.S. Patent Application Publication No. 2005/0133160, which is incorporated herein by reference in its entirety. The showerhead electrode assembly 10 comprises a showerhead electrode including a top electrode 12, a backing member 14 secured to the top electrode 12, and a thermal control plate 16. A substrate support 18 (only a portion of which is shown in FIG. 1) including a bottom electrode and optional electrostatic clamping electrode is positioned beneath the top electrode 12 in the vacuum processing chamber of the plasma processing apparatus. A substrate 20 subjected to plasma processing is mechanically or electrostatically clamped on an upper support surface 22 of the substrate support 18.

In the illustrated embodiment, the top electrode 12 of the showerhead electrode includes an inner electrode member 24, and an optional outer electrode member 26. The inner electrode member 24 is preferably a cylindrical plate (e.g., a plate composed of silicon). The inner electrode member 24 can have a diameter smaller than, equal to, or larger than a wafer to be processed, e.g., up to 12 inches (300 mm) if the plate is made of silicon. In a preferred embodiment, the showerhead electrode assembly 10 is large enough for processing large substrates, such as semiconductor wafers having a diameter of 300 mm or larger. For 300 mm wafers, the top electrode 12 is at least 300 mm in diameter. However, the showerhead electrode assembly can be sized to process other wafer sizes or substrates having a non-circular configuration. In the illustrated embodiment, the inner electrode member 24 is wider than the substrate 20. For processing 300 mm wafers, the outer electrode member 26 is provided to expand the diameter of the top electrode 12 from about 15 inches to about 17 inches. The outer electrode member 26 can be a continuous member (e.g., a continuous poly-silicon ring), or a segmented member (e.g., including 2-6 separate segments arranged in a ring configuration, such as segments composed of silicon). In embodiments of the top electrode 12 that include a multiple-segment, outer electrode member 26, the segments preferably have edges, which overlap each other to protect an underlying bonding material from exposure to plasma. The inner electrode member 24 preferably includes multiple gas passages 28 extending through the backing member 14 for injecting process gas into a space in a plasma reaction chamber located between the top electrode 12 and the bottom electrode 18.

Silicon is a preferred material for plasma exposed surfaces of the inner electrode member 24 and the outer electrode member 26. High-purity, single crystal silicon minimizes contamination of substrates during plasma processing and also wears smoothly during plasma processing, thereby minimizing particles. Alternative materials that can be used for plasma-exposed surfaces of the top electrode 12 include SiC or AlN, for example.

In the illustrated embodiment, the backing member 14 includes a backing plate 30 and a backing ring 32, extending around the periphery of backing plate 30. In the embodiment, the inner electrode member 24 is co-extensive with the backing plate 30, and the outer electrode member 26 is co-extensive with the surrounding backing ring 32. However, the backing plate 30 can extend beyond the inner electrode member 24 such that a single backing plate can be used to support the inner electrode member 24 and the segmented outer electrode member 26. The inner electrode member 24 and the outer electrode member 26 are preferably attached to the backing member 14 by a bonding material.

The backing plate 30 and backing ring 32 are preferably made of a material that is chemically compatible with process gases used for processing semiconductor substrates in the plasma processing chamber, and is electrically and thermally conductive. Exemplary suitable materials that can be used to make the backing member 14 include aluminum, aluminum alloys, graphite and SiC.

The top electrode 12 can be attached to the backing plate 30 and backing ring 32 with a suitable thermally and electrically conductive elastomeric bonding material that accommodates thermal stresses, and transfers heat and electrical energy between the top electrode 12 and the backing plate 30 and backing ring 32. The use of elastomers for bonding together surfaces of an electrode assembly is described, for example, in commonly-owned U.S. Pat. No. 6,073,577, which is incorporated herein by reference in its entirety.

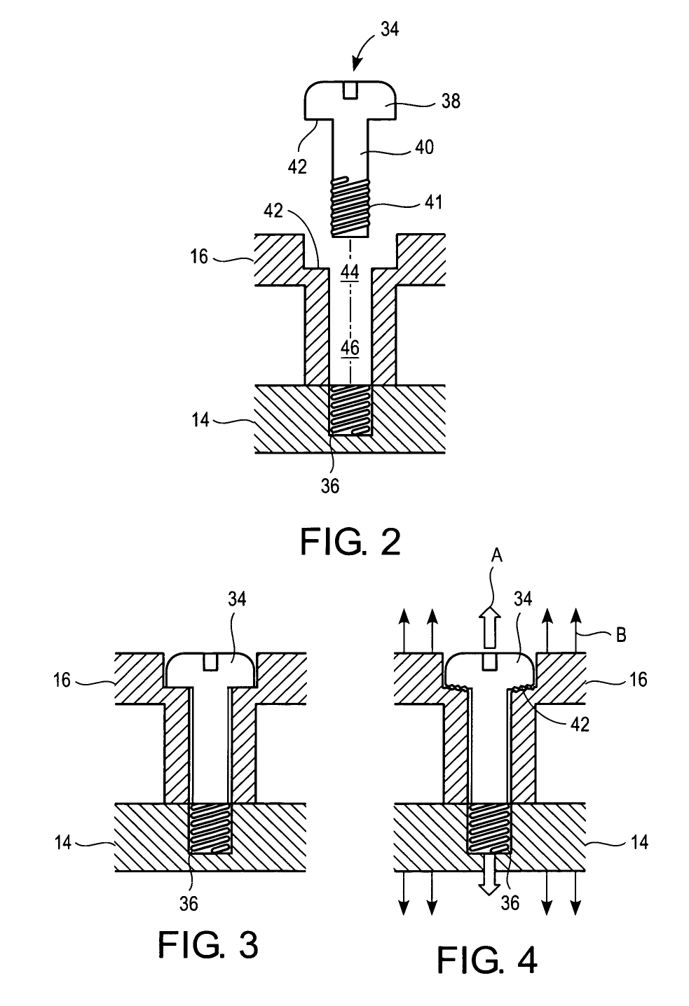

The backing plate 30 and backing ring 32 are attached to the thermal control plate 16 with suitable fastener members. FIG. 2 is an enlarged view of the fastener members 34/36 attaching the backing member 14 (or backing plate 30) to the thermal control plate 16 shown in FIG. 1. In this embodiment, the fastener members 34/36 comprise a first fastener member 34 and a second fastener members 36. The first fastener member 34 preferably includes a head 38, shaft 40, external threads 41, and a load-bearing surface 42. For example, the first fastener member 34 can be a threaded screw, bolt, or the like. In this embodiment, each of the second fastener member 36 engages with the external threads of a respective first fastener member 34. The second fastener member 36 can be a helicoil, any internally threaded structure, or the like. A preferred material for the fastener members 34/36 is Nitronic-60, a stainless steel that provides resistance to galling in a vacuum environment.

The fastener members 34/36 from this embodiment can also be used to attach the backing ring 32, shown in FIG. 1 to the thermal control plate 16.

As shown in FIG. 2, the first fastener member 34 is inserted in the through aperture 44/46 of the thermal control plate 16. The aperture 44/46 in the thermal control plate 16 has a stepped structure and includes a first portion 44 wider than a second portion 46 (e.g., a counter bored hole), and a load-bearing surface 42. The second fastener member 36 is attached to or embedded within a recess in the backing member 14. As the threads of the first fastener member 34 engage the threads of the second fastener member 36, the thermal control plate 16 is secured to the backing member 14. This engagement provides a pre-determined clamping force, which is distributed among the load-bearing surface 42 of the first fastener member 34 and the load-bearing surface of the through aperture 44/46 of the thermal control plate 16.

It has been determined that if the material of the first fastener member 34 has a lower coefficient of thermal expansion than the material of the thermal control plate 16, the clamping force between the backing member 14 and the thermal control plate 16 can increase significantly as these components are heated to an elevated semiconductor substrate plasma process temperature, such as about 80° C. to about 160° C.

For example, in one embodiment, the first fastener member 34 can be made of a stainless steel, such as Nitronic-60, and inserted in the through aperture 44/46 of the aluminum thermal control plate 16. In this embodiment, the second fastener member 36 is a stainless steel helicoil, attached to the aluminum or graphite backing member 14. The thermal control plate 16 is secured to the backing member 14 with the fastener members 36/38 tightened to provide a pre-determined clamping force. FIG. 3 is an illustration of this configuration at ambient temperature.

Upon heating of the structure shown in FIG. 3 to an elevated processing temperature (e.g., about 80° C. to about 160° C.), the aluminum thermal control plate 16 (coefficient of thermal expansion=14×10⁻⁶ (° F.)⁻¹) and stainless steel first fastener member 34 (coefficient of thermal expansion=9.89×10⁻⁶ (° F.)⁻¹) expand at different rates, as illustrated in FIG. 4. The first fastener member 34 must expand in an axial direction (arrows A in FIG. 4) to accommodate the greater thermal expansion of the thermal control plate 16 (arrows B in FIG. 4). In addition, the abutting load-bearing surfaces 42 of the thermal control plate 16 and the first fastener member 34 may deform to accommodate the thermal expansion of the thermal control plate 16. As a result, the clamping force between the aluminum thermal control plate 16 and the backing member 14 increases at elevated processing temperatures. The resulting forces from thermal cycling causes loosening of the fastener members 34/36, due to localized damage to the load-bearing surfaces 42 of the first fastener member 34, the thermal control plate 16, and screw treads, as well as the generation of particulates.

One approach for reducing the localized damage to the load-bearing surfaces 42 and screw threads is to use a first fastener member 34 composed of the same material as the thermal control plate 16, or another material that has a coefficient of thermal expansion that approximates that of the thermal control plate 16. This approach can minimize forces on the load-bearing surfaces 42 of the first fastener member 34 and thermal control plate 16, due to differential thermal expansion because the first fastener member 34 and thermal control plate 16 thermally expand at about the same rate.

It has been determined that the use of the anodized aluminum first fastener member 34 can desirably prevent a significant increase in the clamping force, thus preventing localized damage to the load-bearing surfaces 42 of the first fastener member 34, the thermal control plate 16, and screw threads. For example, the first fastener member 34 (e.g., threaded screw) material can be made of anodized aluminum, and inserted in the through aperture 44/46 of the thermal control plate 16, made of aluminum. The second fastener member 36, a stainless steel helicoil, is attached to a graphite backing member 14. The thermal control plate 16 is secured to the backing member 14 with the fastener members 34/36 at a pre-determined clamping force. However, a large number of particles can be generated from the flaking of the anodized coating from the first fastener member 34, due to the differential expansion between the anodized aluminum first fastener members 34 (e.g., screws) and stainless steel second fastener members 36 (e.g., helicoil). Accordingly, in a plasma processing chamber in which such contamination is highly undesirable, the first fastening member 34 should be made of a material that has a suitable coefficient of thermal expansion and which also does not introduce contaminants during plasma processing.

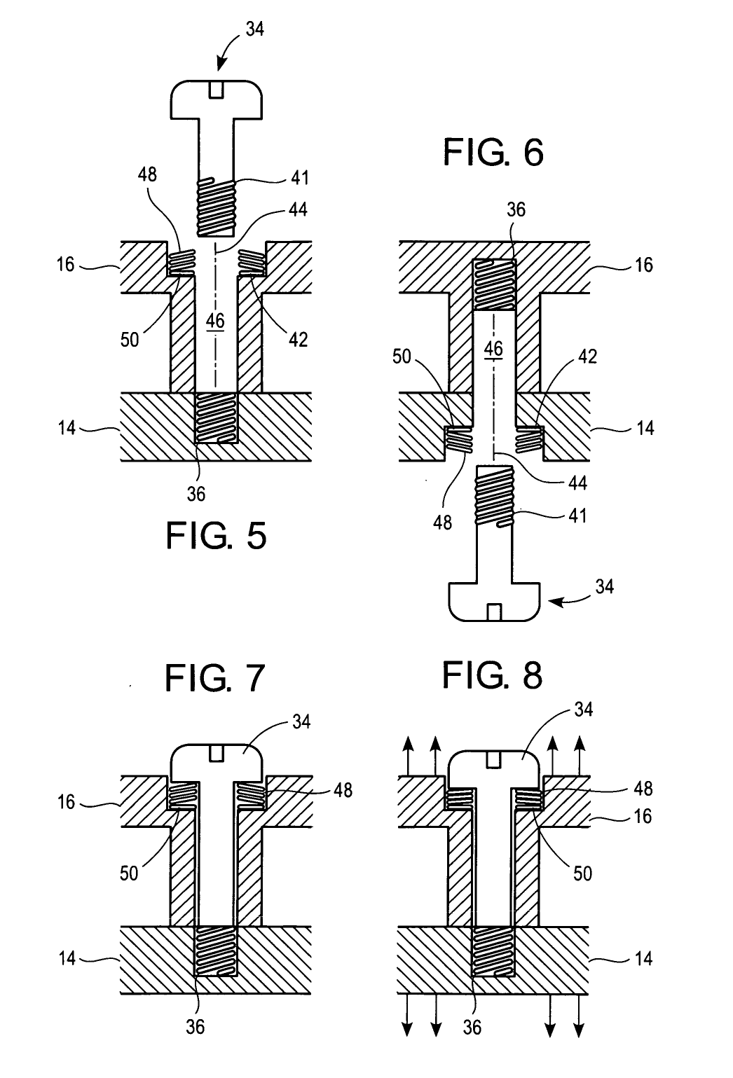

FIG. 5 is an enlarged view of an exemplary embodiment for attaching the backing member 14 (or backing plate 30) to the thermal control plate 16, which can address both of the previous problems, stresses generated by thermal expansion and the flaking of particulate contaminants. In this embodiment, the first fastener member 34 (e.g., threaded screw) material is stainless steel and inserted in the through aperture 44/46 of the aluminum thermal control plate 16. The second fastener member 36 is a stainless steel Nitronic-60 helicoil attached to the aluminum or graphite backing member 14. A deflectable spacer member 48 is mounted in the first portion of the aperture 44, between the load-bearing surface of the first fastener member 34 and the load-bearing surface 42 of thermal control plate 16. For example, the deflectable spacer member 48 can be one of more disc springs (e.g., BELLEVILLE washer) having the same or different spring constants, a helical spring, or any mechanical structure in which the force required to deflect the deflectable spacer member 48 is significantly less (e.g., an order of magnitude) than the force required to deform the first fastener member 34 or the load-bearing surface 42.

FIG. 6 is another exemplary embodiment, in which the through aperture 44/46 is formed in the backing member 14. For this configuration, the aperture 44/46 is formed in the backing member 14 and has a stepped structure, including a first portion 44 which is wider than the second portion 46 (e.g., a counter bored hole), and a load-bearing surface 42. A deflectable spacer member 48 is mounted in the first portion of the aperture 44, between the load-bearing surface 42 of the first fastener member 34 and the load-bearing surface 42 of backing member 14. The second fastener member 36 is attached to or embedded within the thermal control plate 16.

As illustrated in FIG. 7, the first fastener member 34 is secured to the second fastener member 36, such that the deflectable spacer member 48 (e.g., disc spring) is not completely flat at ambient temperature. FIG. 8 depicts the structure shown in FIG. 7 at an elevated temperature (e.g., about 80° C. to about 160° C.). As seen in FIG. 8, the force of thermal expansion is accommodated by the deformable spacer member 48 (i.e., the disc spring is compressed), rather than deforming the first fastener member 34 or deforming the load-bearing surfaces 42 of the thermal control plate 16 and first fastener member 34.

The fastener members 34/36 with deformable spacer member 48 from this embodiment can also be used to attach the backing ring 32 shown in FIG. 1 to the thermal control plate 16.

The force of the deformable spacer member 48 against the anodized aluminum coating of the thermal control plate 16 may also cause some flaking of the anodized coating, potentially introducing particulate matter onto the wafer. To minimize such features, a flat washer 50 can be mounted between the load-bearing surface 42 of the thermal control plate 16 and the deformable spacer member 48. Preferably, flat washer 50 is made of hardened stainless steel (e.g., precipitation hardened stainless steel PH17-4-H900).

The embodiments of FIGS. 5-8 are advantageous because: (i) the deformable spacer member 48 accommodates the stresses generated by the thermal expansion of the thermal control plate 16, thus minimizing damage to the load-bearing surfaces 42 and screw threads; and (ii) can use a Nitronic-60 stainless steel helicoil, a material that provides resistance to galling in a vacuum environment. As described above and depicted in FIG. 4, a disadvantage associated with using only a stainless steel screw without the deformable spacer member 48 is that the stresses generated by thermal expansion can damage the load-bearing surfaces 42 and threads and cause particle generation. Although anodized aluminum fasteners can alleviate stresses generated by thermal expansion, they are susceptible to flaking of particulate contaminants. Thus, the use of the deformable spacer members 48 provides additional flexibility in selecting materials well-suited for a vacuum processing environment, while minimizing the detrimental effects associated with differences in the coefficient of thermal expansion of various materials. Moreover, thermal control plate 16, deformable spacer member 48, and first fastener member 34 can be formed with any suitable materials that can provide resistance to erosion to gases used in a plasma environment, while minimizing particulate contamination during plasma processing.

The embodiments FIGS. 5-8 can be used to attach any two members in a plasma processing apparatus that are heated and can potentially introduce particulate matter. For example, the first and second fastener members 34/36 and deformable spacer member 48 can be used to attach components of substrate support 18 that are subjected to thermal stresses due to the heating and cooling of the plasma processing apparatus.

### EXAMPLE 1

Thermal cycle tests were performed to determine the effect of the first fastener member 36 material on particle generation during heating to an elevated processing temperature in a EXELAN®FLEX™ dielectric plasma etch system, manufactured by Lam Research Corporation, located in Fremont, Calif. For these tests, the generation of particles over 0.09 μm for anodized aluminum screws was compared with that from Nitronic-60 stainless steel screws. The tests were performed by clamping an aluminum thermal control plate 16 to a graphite backing member 14, similar to the configuration illustrated in FIG. 3. During the testing of anodized aluminum screws, a flat washer, similar to flat washer 50, was mounted between the load-bearing surface 42 of the thermal control plate 16 and the screw. A second fastener member 36, a Nitronic-60 stainless steel helicoil, was embedded within graphite backing member 14. The clamped aluminum thermal control plate 16 and graphite backing member 14 were placed in the plasma etch chamber and positioned above a silicon wafer with a baseline particle count. The chamber was heated to a temperature of about 110-115° C. in an inert gas without generating a plasma, causing the clamped aluminum thermal control plate 16 and graphite backing member 14 to thermally expand. The chamber was then cooled to ambient temperature in an inert gas, allowing the clamped aluminum thermal control plate 16 and graphite backing member 14 to contract. For multiple tests, silicon wafer surfaces were then analyzed with an optical surface analyzer for the number of particles larger than 0.09 μm (the analyzer saturates for a particle count of about 20,000). As seen in Table 1, stainless steel screws generated substantially (i.e., an order of magnitude) fewer particles larger than 0.09 μm as compared to the anodized aluminum screws.

TABLE 1

| Material | Particle Count (>0.09 μm) |
|---|---|
| Anodized Aluminum | >20,000 |
| Stainless Steel | ˜5,000 |

### EXAMPLE 2

Tests were performed to measure the clamping force between the thermal control plate 16 and backing member 14 for three screw configurations: (i) stainless steel screw; (ii) anodized aluminum screw; and (iii) stainless steel screw with disc spring. A 500 pound load cell was incorporated between two aluminum test fixtures, constructed to simulate thermal control plate 16 and backing member 14 with a through aperture 44/46. A second fastening member 36, a Nitronic-60 stainless steel helicoil, was embedded into the aluminum fixture simulating backing member 14. During the testing of anodized aluminum screws, a flat washer, similar to flat washer 50, was mounted between the fixture constructed to simulate thermal control plate 16 and the screw. Each of the different screw configurations was tightened to half the final torque, followed by tightening to a final torque (e.g., 12 in-lb. or 15 in-lb.) and obtaining a clamping force measurement from the 500 pound load cell. The threads of the screw and the second portion of the through aperture were cleaned before the test was repeated. As summarized in Table 2 below, the stainless steel screw with the spring discs demonstrated the highest median clamping force and smallest standard deviation for the lower final torque. These characteristics are beneficial in providing a higher, more uniform clamping force, at a lower torque to facilitate disassembly and reassembly of the plasma processing apparatus during routine maintenance.

TABLE 2

| Screw | Final Torque | Median Clamping | Standard |
|---|---|---|---|
| Configuration | (in-lbs.) | Force (lbs.) | Deviation (lbs.) |
| Stainless Steel/Disc | 12 | 276.4 | 13.3 |
| Springs | | | |
| Stainless Steel | 15 | 258.4 | 18.6 |
| Anodized Alum- | 15 | 202.3 | 21.3 |
| inum | | | |

While the invention has been described in detail with reference to specific embodiments thereof, it will be apparent to those skilled in the art that various changes and modifications can be made, and equivalents employed, without departing from the scope of the appended claims.

1-35. (canceled)

36. A component for a plasma processing apparatus, comprising:
a first member having a first coefficient of thermal expansion and including a plurality of through apertures having a first portion and a second portion wider than the first portion, the second portion partially defined by at least one load-bearing surface;
a plurality of first fastener members having a second coefficient of thermal expansion and mounted in the apertures of the first member, the first fastener members including a load-bearing surface;
at least one deflectable spacer mounted between the load-bearing surface defining the second portion of the aperture and the load-bearing surface of the first fastener member; and
a second fastener member engaged with each first fastener member to secure the first member to the second member at a predetermined clamping force, the at least one deflectable spacer adapted to accommodate forces generated during thermal cycling between room temperature and an elevated processing temperature.

37. The component of claim 36, wherein: (a) the deflectable spacer member is adapted to substantially reduce the generation of particles from the first member or first fastener member during the thermal cycling or (b) the at least one deflectable spacer is one or more disc springs in the same aperture.

38. The component of claim 37, further comprising a flat washer mounted between each deflectable spacer and load-bearing surface of the first member.

39. The component of claim 36, wherein: (a) each of the first fastener members comprises external threads, and each of the second fastener members comprises internal threads engaged with the external threads of a respective first fastener member: (b) the first coefficient of thermal expansion is greater than the second coefficient of thermal expansion; (c) the first coefficient of thermal expansion is substantially equal to the second coefficient of thermal expansion; or (d) the first member is a thermal control plate.

40. The component of claim 36, wherein: (a) the first member is a thermal control plate composed of aluminum or an aluminum alloy material and/or (b) the second member is a backing member.

41. The component of claim 40, wherein: (a) the backing member comprises a backing plate and a backing ring extending around the periphery of the backing plate and/or (b) the backing member is composed of aluminum or graphite.

42. The component of claim 36, further comprising a third member attached to the second member.

43. The component of claim 42, wherein the third member is an electrode.

44. The component of claim 43, wherein the electrode comprises an inner silicon electrode and an outer silicon electrode.

45. A component for a plasma processing apparatus, comprising:
a first member having a first coefficient of thermal expansion;
a second member including a plurality of through apertures having a first portion and a second portion wider than the first portion, the second portion partially defined by at least one load-bearing surface;
a plurality of first fastener members having a second coefficient of thermal expansion and mounted in the apertures of the second member, each of the first fastener members including a load-bearing surface;
at least one deflectable spacer mounted between the load-bearing surface defining the second portion of the aperture and the load-bearing surface of the first fastener member; and
a second fastener member engaged with each first fastener member to secure the first member to the second member at a predetermined clamping force, the at least one deflectable spacer adapted to accommodate forces generated during thermal cycling between room temperature and an elevated processing temperature.

46. The component of claim 45, wherein: (a) the deflectable spacer member is adapted to substantially reduce the generation of particles from the first member or first fastener member during the thermal cycling and/or (b) the at least one deflectable spacer is one or more disc springs.

47. The component of claim 46, further comprising a flat washer mounted between each deflectable spacer and load-bearing surface of the second member.

48. The component of claim 45, wherein: (a) each of the first fastener members comprises external threads, and each of the second fastener members comprises internal threads engaged with the external threads of a respective first fastener member; (b) the first coefficient of thermal expansion is greater than the second coefficient of thermal expansion or the first coefficient of thermal expansion is substantially equal to the second coefficient of thermal expansion; (c) the first member is a thermal control plate; (d) the first member is a thermal control plate composed of aluminum or an aluminum alloy material; (e) the second member is a backing member.

49. The component of claim 48, wherein: (a) the backing member comprises a backing plate and a backing ring extending around the periphery of the backing plate; (b) the backing member is composed of aluminum or graphite; and/or (c) further comprising a third member attached to the second member.

50. The component of claim 49, wherein: (a) the third member is an electrode and/or (b) the third member comprises an inner silicon electrode and an outer silicon electrode.

51. A showerhead electrode assembly for a plasma processing apparatus, comprising:
an aluminum thermal control plate including a plurality of through apertures having a first portion and a second portion wider than the first portion, the second portion partially defined by at least one load-bearing surface;
a plurality of stainless steel fastener members mounted in the apertures of the thermal control plate, the first fastener members including a load-bearing surface;
a plurality of deflectable spacers mounted between the load-bearing surface of the second portion of the aperture and the load-bearing surface of the first fastener member;
a second fastener member engaged with each first fastener member to secure the thermal control plate to a backing member at a predetermined clamping force, the deflectable spacers adapted to accommodate forces generated by the difference in thermal expansion between the thermal control plate and first fastener members during thermal cycling between room temperature and an elevated processing temperature; and
a silicon electrode attached to the backing plate.

52. The showerhead electrode assembly of claim 51, wherein: (a) the at least one deflectable spacer is one or more disc springs; (b) further comprising a flat washer mounted between each deflectable spacer and load-bearing surface of the thermal control plate; (c) each of the stainless steel fastener members comprises external threads, and each of the second fastener members comprises internal threads engaged with the internal threads of a respective stainless steel fastener member.

53. A method of processing a semiconductor substrate in a plasma processing apparatus, the method of comprising:
placing a substrate on a substrate support in a reaction chamber of a plasma processing apparatus;
introducing a process gas into the reaction chamber with the showerhead electrode assembly of claim 51;
generating a plasma from the process gas between the showerhead electrode assembly and the substrate; and
processing the substrate with the plasma.
